(19) United States
(12) Patent Application Publication
(10) Pub. No.: US 2022/0146932 A1
(43) Pub. Date: May 12, 2022

(54) PHOTOSENSITIVE RESIN COMPOSITION, METHOD FOR FORMING RESIST PATTERN, AND METHOD FOR PRODUCING PLATED FORMED PRODUCT

(71) Applicant: JSR CORPORATION, Tokyo (JP)

(72) Inventors: Hiroto NODA, Minato-ku, Tokyo (JP); Taku OGAWA, Minato-ku, Tokyo (JP); Shuhei HORIKAWA, Minato-ku, Tokyo (JP); Kazuhiko KOUMURA, Minato-ku, Tokyo (JP)

(73) Assignee: JSR CORPORATION, Tokyo (JP)

(21) Appl. No.: 17/438,962

(22) PCT Filed: Feb. 13, 2020
(86) PCT No.: PCT/JP2020/005444

§ 371 Date: Sep. 14, 2021

(30) Foreign Application Priority Data
Mar. 22, 2019 (JP) 2019-054643

(51) Int. Cl. G03F 7/033; C08F 220/18; C08F 212/14

(52) U.S. Cl. CPC G03F 7/033; C08F 220/1809; C08F 212/24; C08F 220/1811

(57) ABSTRACT

The present invention is a photosensitive resin composition including an alkali-soluble resin (A), a polymerizable compound (B), a photoradical polymerization initiator (C), and a solvent (D), in which the polymerizable compound (B) contains at least one kind (B1) selected from a compound represented by the following formula (1) and a compound represented by the following formula (3), having specific Rs, and a content ratio of the compound (B1) contained in the photosensitive resin composition is 15 to 50% by mass. The photosensitive resin composition of the present invention can form a thick-film resist pattern having excellent sensitivity and resolution, and by using the thick-film resist pattern, a plated formed product can be miniaturized.

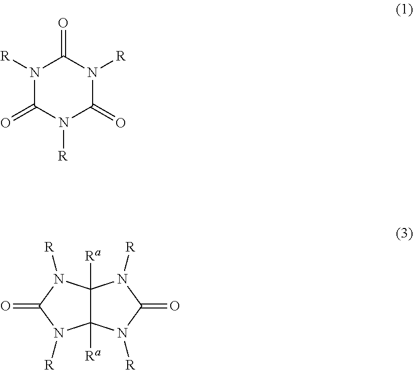

### TECHNICAL FIELD

The present invention relates to a photosensitive resin composition, a method for forming a resist pattern, and a method for producing a plated formed product.

### BACKGROUND ART

In recent years, since there has been an increasing demand for the high-density mounting of a connection terminal such as a bump of a semiconductor element or a display element such as a liquid crystal display or a touch panel, the miniaturization of a connection terminal has been progressing.

In general, a bump and the like are plated formed products, and are produced by forming a thick-film resist pattern on a substrate having a metal foil such as copper, and by plating the substrate with the use of the thick-film resist pattern as a mask, as disclosed in Patent Literature 1.

For this reason, with the miniaturization of a bump and the like, it is becoming necessary to miniaturize a resist pattern for use in the production of the bump and the like.

### CITATION LIST

### Patent Literature

Patent Literature 1: JP 2006-285035 A

### SUMMARY OF INVENTION

### Technical Problem

In order to form a thick-film resist pattern from a photosensitive resin composition, it is required to increase the viscosity of the photosensitive resin composition. As the method for increasing the viscosity of the photosensitive resin composition, a method of filling particles of silica or the like in the photosensitive resin composition can be mentioned, but with this method, there are some problems of viscosity changes due to the dispersion stability and moisture absorption of the particles, reduction in resolution due to the presence of the particles, and the like, and as a result, it is difficult to miniaturize the resist pattern.

The objects of the present invention are to provide a photosensitive resin composition capable of forming a thick-film resist pattern having excellent sensitivity and resolution, and to provide a method for forming a thick-film resist pattern and a method for producing a plated formed product using the thick-film resist pattern.

### Solution to Problem

The present invention that achieves the above object relates to, for example, the following [1] to [5].

[1] A photosensitive resin composition including an alkali-soluble resin (A), a polymerizable compound (B), a photoradical polymerization initiator (C), and a solvent (D), in which the polymerizable compound (B) contains at least one kind (B1) selected from a compound represented by the following formula (1) and a compound represented by the following formula (3), and a content ratio of the compound (B1) contained in the photosensitive resin composition is 15 to 50% by mass.

### [Chemical Formula 1]

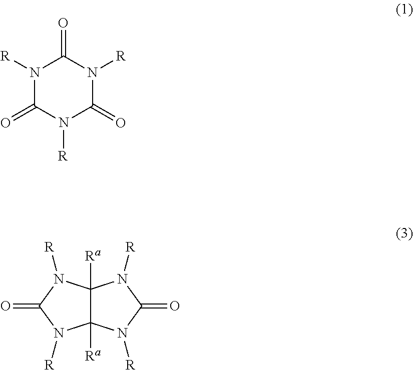

(In the formulas (1) and (3), Rs each independently represent any one of the groups represented by the following formulas (1-1) to (1-3), at least one R of the three Rs in the formula (1) and at least one R of the four Rs in the formula (3) each represent a group represented by the following formula (1-1), and R^{a}s in the formula (3) each independently represent a hydrogen atom, or a methyl group.)

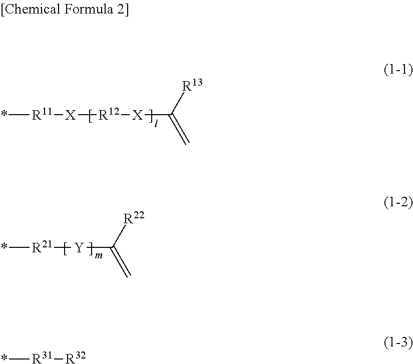

(In the formulas, R¹¹ represents an alkanediyl group having 1 to 10 carbon atoms, R¹² represents a hydrocarbon group having 3 to 10 carbon atoms, R¹³ represents a hydrogen atom, an alkyl group having 1 to 10 carbon atoms, or a fluorinated alkyl group having 1 to 10 carbon atoms, X represents —COO— or —OCO—, R²¹ represents an alkanediyl group having 1 to 3 carbon atoms, R²² represents a hydrogen atom, an alkyl group having 1 to 7 carbon atoms, or a fluorinated alkyl group having 1 to 7 carbon atoms, Y represents —COO— or —OCO—, R³¹ represents an alkanediyl group having 1 to 3 carbon atoms, R³² represents a hydroxyl group, a carboxyl group, a mercapto group, or an epoxy group, 1 is an integer of 1 to 3, and m is an integer of 0 to 1.)

[2] The photosensitive resin composition described in [1], in which a content ratio of the compound (B1) to the total content of the alkali-soluble resin (A) and the polymerizable compound (B) is 20 to 50% by mass.

[3] The photosensitive resin composition described in [1] or [2], in which a content ratio of the compound (B1) contained in the polymerizable compound (B) is 50 to 100% by mass.

[4] The photosensitive resin composition described in [1], in which the polymerizable compound (B1) is a compound represented by the above formula (1).

[5] A method for forming a resist pattern including a step (1) of forming a resin-coated film by applying the photosensitive resin composition according to any one of [1] to [4] onto a substrate; a step (2) of exposing the resin-coated film, and a step (3) of developing the exposed resin-coated film.

[6] A method for producing a plated formed product including a step of performing plating treatment by using the resist pattern formed by the method for forming a resist pattern described in [5] as a mask.

### Advantageous Effects of Invention

The photosensitive resin composition of the present invention can form a thick-film resist pattern having excellent sensitivity and resolution, and by using the thick-film resist pattern, a plated formed product can be miniaturized.

### DESCRIPTION OF EMBODIMENTS

The photosensitive resin composition of the present invention contains an alkali-soluble resin (A), a polymerizable compound (B), a photoradical polymerization initiator (C), and a solvent (D). By containing a specific compound to be described later as the polymerizable compound (B) in a specific proportion, the photosensitive resin composition of the present invention exerts the effect of the present invention, which can form a thick-film resist pattern having excellent resolution.

[Photosensitive Resin Composition]

The alkali-soluble resin (A) is a resin having a property of being dissolved in an alkaline developer to the extent that the desired development treatment can be performed. By the photosensitive resin composition of the present invention containing an alkali-soluble resin (A), the resistance to a plating liquid can be imparted to the resist, and the development can be performed with an alkaline developer.

Examples of the alkali-soluble resin (A) include alkali-soluble resins disclosed in JP 2008-276194 A, JP 2003-241372 A, JP 2009-531730 W, WO 2010/001691, JP 2011-123225 A, JP 2009-222923 A, JP 2006-243161 A, and the like.

The weight average molecular weight (Mw) in terms of polystyrene of an alkali-soluble resin (A) measured by gel permeation chromatography is in the range of usually 1,000 to 1,000,000, preferably 2,000 to 50,000, and more preferably 3,000 to 20,000.

It is preferable that the alkali-soluble resin (A) has a phenolic hydroxyl group, in the point of improving the plating-liquid resistance of a resist.

As the alkali-soluble resin (A) having the phenolic hydroxyl group, an alkali-soluble resin (A1) having a structural unit represented by the following formula (2) is preferred.

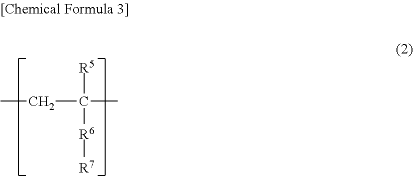

(In the formula (2), R⁵ represents a hydrogen atom, a substituted or unsubstituted alkyl group having 1 to 10 carbon atoms, or a halogen atom, R⁶ represents a single bond or an ester bond, and R⁷ represents a hydroxyaryl group.)

By using an alkali-soluble resin (A1) as the alkali-soluble resin (A), a resist pattern that does not easily swell can be obtained in a step (4) of performing plating treatment on a substrate to be described later. As a result, the lifting and peeling of a resist pattern from a base material do not generate, and thus it is possible to prevent a plating liquid from seeping out to the interface between the base material and the resist pattern even in a case where the plating is performed for a long time. Further, by using the alkali-soluble resin (A1) as the alkali-soluble resin (A), the resolution of the photosensitive resin composition can also be made favorable.

Such alkali-soluble resins (A) may be used singly alone, or in combination of two or more kinds thereof.

The content of the alkali-soluble resin (A) is usually 100 to 300 parts by mass, and preferably 150 to 250 parts by mass, with respect to 100 parts by mass of the polymerizable compound (B). If the content of the alkali-soluble resin is in the above range, a resist having excellent plating-liquid resistance can be formed.

When a coated film is formed by applying the negative-type photosensitive resin composition of the present invention onto a substrate, and the coated film is exposed, the polymerizable compound (B) polymerizes at a radically-polymerizable unsaturated double bond group in the exposed portion due to the action of the radicals generated from the photoradical polymerization initiator (C) to form a crosslinked body.

The polymerizable compound (B) contains at least one kind (B1) selected from a compound (B1) represented by the following formula (1) and a compound represented by the following formula (3).

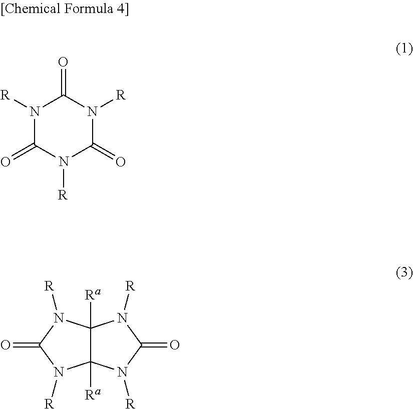

In the formulas (1) and (3), Rs each independently represent any one of the groups represented by the following formulas (1-1) to (1-3). At least one of the three Rs in the formula (1) is a group represented by the above formula (1-1), at least two of the three Rs are each preferably a group represented by the above formula (1-1), and all of the three Rs are each particularly preferably a group represented by the above formula (1-1). At least one R of the four Rs in the (3) represents a group represented by the following formula (1-1), at least two of the four Rs are each preferably a group represented by the above formula (1-1), at least three of the four Rs are each more preferably a group represented by the above formula (1-1), and all of the four Rs are each particularly preferably a group represented by the above formula (1-1).

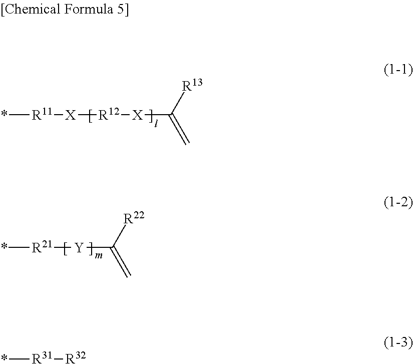

In the formula (1-1), R¹¹ represents an alkanediyl group having 1 to 10 carbon atoms. Examples of the alkanediyl group include a methylene group, an ethylene group, a propane-1,2-diyl group, a propane-2,2-diyl group, a propane-1,3-diyl group, a butane-1,4-diyl group, and a pentane-1,5-diyl group. R¹¹ is particularly preferably a methylene group.

R¹² represents a hydrocarbon group having 3 to 10 carbon atoms. Examples of the hydrocarbon group include an alkanediyl group, and an arylene group. Examples of the alkanediyl group include groups similar to the groups described above. Examples of the arylene group include a 1,4-phenylene group, and a 2,7-naphthylene group. R¹² is particularly preferably a pentane-1,5-diyl group.

R¹³ represents a hydrogen atom, an alkyl group having 1 to 10 carbon atoms, or a fluorinated alkyl group having 1 to 10 carbon atoms. Examples of the alkyl group include a methyl group, an ethyl group, a propyl group, and a butyl group. Examples of the fluorinated alkyl group include groups obtained by replacing one or more hydrogen atoms of the alkyl group with fluorine atoms. R¹³ is particularly preferably a hydrogen atom.

X represents —COO—, or —OCO—.

l is an integer of 1 to 3, and is particularly preferably 1.

In the formula (1-2), R²¹ represents an alkanediyl group having 1 to 3 carbon atoms. Examples of the alkanediyl group include a methylene group, an ethylene group, a propane-1,2-diyl group, a propane-2,2-diyl group, and a propane-1,3-diyl group. R²¹ is particularly preferably a methylene group.

R²² represents a hydrogen atom, an alkyl group having 1 to 7 carbon atoms, or a fluorinated alkyl group having 1 to 7 carbon atoms. Examples of the alkyl group include a methyl group, an ethyl group, a propyl group, and a butyl group. Examples of the fluorinated alkyl group include groups obtained by replacing one or more hydrogen atoms of the alkyl group with fluorine atoms. R²² is particularly preferably a hydrogen atom.

Y represents —COO—, or —OCO—.

m is an integer of 0 to 1, and is particularly preferably 1.

In the formula (1-3), R³¹ represents an alkanediyl group having 1 to 3 carbon atoms. Examples of the alkanediyl group include groups similarly to those of the above R²¹.

R³² represents a hydroxyl group, a carboxyl group, a mercapto group, or an epoxy group.

R^{a}s in the formula (3) each independently represent a hydrogen atom, or a methyl group.

Specific examples of the compound (B1) include the polymerizable compounds (B11), (B12), (B13), and the like used in Examples to be described later. If a compound (B1) such as the polymerizable compounds (B11), (B12), and (B13) is used, a photosensitive resin composition having an adequate viscosity is obtained, and a thick-film resist pattern having excellent sensitivity and resolution can be formed. On the other hand, even though the structure of a compound is similar to that of the polymerizable compound (B11) or (B12), if a compound such as a polymerizable compound (B21) used in Comparative Examples to be described later is used, a photosensitive resin composition having a low viscosity is obtained, a photosensitive resin composition having an adequate viscosity cannot be obtained, and thus a thick-film resist pattern having excellent sensitivity and resolution cannot be formed. This is considered to be due to the following reasons.

It is considered that the viscosity of the photosensitive resin composition is adjusted by a combination of a factor that enhances the crystallinity existing in the molecule of the polymerizable compound and a factor that inhibits the above crystallinity, and by an adequate combination of both factors, a loose fluidity is exhibited, and a suitable viscosity is obtained. By selecting a combination of the both factors, a polymerizable compound having a certain level or higher viscosity can be obtained even if it is a low-molecular weight compound having fluidity. A compound such as the polymerizable compounds (B11), (B12), and (B21) has an isocyanuric ring, and a substituent bound to the isocyanuric ring, a polymerizable compound (B13) has a glycoluril ring, and a substituent bound to the glycoluril ring, and it is considered that the isocyanuric ring and the glycoluril ring are factors that enhance the crystallinity, and the substituents are factors that inhibit the crystallinity. Since a compound such as the polymerizable compounds (B11), (B12), and (B13) has a relatively long group of —C₂H₄OCOC₅H₁₀OCOCH═CH₂ as the substituent, a factor that inhibits the crystallinity is relatively strong, and for this reason, it is considered that the factor that enhances the crystallinity and the factor that inhibits the crystallinity are adequately adjusted, and the photosensitive resin composition can exhibit a suitable viscosity, and as a result, a thick-film resist pattern having excellent sensitivity and resolution can be formed. On the other hand, since a compound such as a polymerizable compound (B21) has only a relatively short group of —C₂H₄OCOCH═CH₂, a factor that inhibits the crystallinity is relatively weak, and for this reason, it is considered that the factor that enhances the crystallinity and the factor that inhibits the crystallinity are not adequately adjusted, and the photosensitive resin composition cannot exhibit a suitable viscosity and has a low viscosity, and as a result, a thick-film resist pattern having excellent resolution cannot be formed.

The content ratio of the compound (B1) in the photosensitive resin composition of the present invention is 15 to 50% by mass, preferably 15 to 45% by mass, and more preferably 15 to 40% by mass. If the content ratio of the compound (B1) is less than 15% by mass, not only the resist pattern cannot be thickened, but also the sensitivity and resolution of the photosensitive resin composition cannot be improved. On the other hand, if the content ratio of the compound (B1) exceeds 50% by mass, most of the photosensitive resin composition becomes a compound (B1), and thus the resist pattern cannot be thickened.

Further, the proportion of the content of the compound (B1) to the total content of the alkali-soluble resin (A) and the polymerizable compound (B) is preferably 20 to 50% by mass, and more preferably 20 to 45% by mass, from the viewpoint of being suitable for forming a thick-film resist pattern having excellent sensitivity and resolution.

The polymerizable compound (B) can also contain a compound other than the compound (B1). Examples of the compound other than the compound (B1) include polyfunctional (meth)acrylates such as 2-hydroxyethyl (meth)acrylate, 2-hydroxypropyl (meth)acrylate, 2-hydroxybutyl (meth)acrylate, phenoxy polypropylene glycol (meth)acrylate, a reactant of phthalic acid and epoxy (meth)acrylate, tricyclo[5.2.1.0^{2,6}]decadienyl (meth)acrylate, tricyclo[5.2.1.0^{2,6}]decanyl (meth)acrylate, tricyclo[5.2.1.0^{2,6}]decenyl (meth)acrylate, isobornyl (meth)acrylate, trimethylolpropane di(meth)acrylate, trimethylolpropane tri(meth)acrylate, trimethylolpropane PO (propylene oxide)-modified tri(meth)acrylate, bisphenol A di(meth)acryloyloxymethyl ethyl ether, bisphenol A di(meth)acryloyloxyethyl oxy ethyl ether, pentaerythritol tri(meth)acrylate, pentaerythritol tetra (meth)acrylate, dipentaerythritol penta (meth)acrylate, dipentaerythritol hexa (meth)acrylate, and polyester (meth)acrylate.

The content ratio of the compound (B1) in the polymerizable compound (B) is preferably 50 to 100% by mass, more preferably 60 to 100% by mass, and furthermore preferably 70 to 100% by mass, from the viewpoints of being suitable for thickening the resist pattern and of being suitable for improving the sensitivity and resolution of the photosensitive resin composition.

Examples of the photoradical polymerization initiator (C) include an oxime-based compound, an organic halogenated compound, an oxadiazole compound, a carbonyl compound, a ketal compound, a benzoin compound, an acridine compound, an organic peroxide compound, an azo compound, a coumarin compound, an azide compound, a metallocene compound, a hexaarylbiimidazole compound, an organic boric acid compound, a disulfonic acid compound, an onium salt compound, and an acyl phosphine (oxide) compound. Among them, from the viewpoint of the sensitivity, an oxime-based photoradical polymerization initiator, particularly a photoradical polymerization initiator having an oxime ester structure is preferable.

In the photoradical polymerization initiator having an oxime ester structure, geometric isomers due to the double bond of the oxime may be present, but these are not distinguished, and all of them are included in the photoradical polymerization initiator (C).

Examples of the photoradical polymerization initiator having an oxime ester structure include photoradical polymerization initiators disclosed in WO 2010/146883, JP 2011-132215 A, JP 2008-506749 W, JP 2009-519904 W, and JP 2009-519991 W.

Specific examples of the photoradical polymerization initiator having an oxime ester structure include N-benzoyloxy-1-(4-phenylsulfanylphenyl)butane-1-one-2-imine, N-ethoxycarbonyloxy-1-phenylpropane-1-one-2-imine, N-benzoyloxy-1-(4-phenylsulfanylphenyl)octane-1-one-2-imine, N-acetoxy-1-[9-ethyl-6-(2-methylbenzoyl)-9H-carbazol-3-yl]ethane-1-imine, N-acetoxy-1-[9-ethyl-6-{2-methyl-4-(3,3-dimethyl-2,4-dioxacyclopentanylmethyloxy) benzoyl}-9H-carbazol-3-yl]ethane-1-imine, and 1-[9-ethyl-6-(2-methylbenzoyl)-9H-carbazol-3-yl]ethanone 1-(0-acetyloxime).

Such photoradical polymerization initiators (C) may be used singly alone, or in combination of two or more kinds thereof.

The content of the photoradical polymerization initiator (C) in the present photosensitive resin composition is usually 1 to 40 parts by mass, preferably 3 to 35 mass, and more preferably 5 to 30 parts by mass, with respect to 100 parts by mass of the polymerizable compound (B). If the content of the photoradical polymerization initiator (C) is within the above range, a suitable amount of radicals can be obtained, and excellent sensitivity and resolution can also be obtained.

The solvent (D) improves the handleability of the photosensitive resin composition, facilitates the adjustment of the viscosity, and also improves the storage stability.

Examples of the solvent (D) include

alcohols such as methanol, ethanol, and propylene glycol;

cyclic ethers such as tetrahydrofuran, and dioxane;

glycols such as ethylene glycol, and propylene glycol;

alkylene glycol monoalkyl ethers such as ethylene glycol monomethyl ether, propylene glycol monomethyl ether, and propylene glycol monoethyl ether;

alkylene glycol monoalkyl ether acetates such as ethylene glycol monomethyl ether acetate, propylene glycol monomethyl ether acetate, and propylene glycol monoethyl ether acetate;

aromatic hydrocarbons such as toluene, and xylene;

ketones such as acetone, methyl ethyl ketone, methyl isobutyl ketone, cyclohexanone, and 4-hydroxy-4-methyl-2-pentanone;

esters such as ethyl acetate, butyl acetate, ethyl ethoxyacetate, ethyl hydroxyacetate, ethyl 2-hydroxypropionate, ethyl 2-hydroxy-2-methylpropionate, methyl 2-hydroxy-3-methylbutyrate, methyl 3-methoxypropionate, ethyl 3-methoxypropionate, ethyl 3-ethoxypropionate, methyl 3-ethoxypropionate, and ethyl lactate;

N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, γ-butyrolactone, ethylene carbonate, propylene carbonate, and phenyl cellosolve acetate.

Such solvents may be used singly alone, or in combination of two or more kinds thereof.

In a case where a resist pattern having a film thickness of 0.1 to 200 μm is formed, the amount of the solvent to be used may be set to an amount with which the solid content of the photosensitive resin composition is 5 to 80% by mass.

The photosensitive resin composition of the present invention may contain a surfactant, an adhesive auxiliary, a sensitizer, an inorganic filler, a polymerization inhibitor, and the like as other components, within the range not impairing the object and characteristics of the present invention. However, if the photosensitive resin composition of the present invention contains particles of pigment, silica or the like, the viscosity changes due to the dispersion stability and moisture absorption of the particles, and the reduction in resolution due to the presence of the particles may be generated, and thus it is preferable that the photosensitive resin composition does not contain such particles.

The photosensitive resin composition of the present invention can be produced by uniformly mixing the above components.

[Method for Forming Resist Pattern]

The method for forming a resist pattern of the present invention includes: a step (1) of forming a resin-coated film by applying the photosensitive resin composition onto a substrate; a step (2) of exposing the resin-coated film; and a step (3) of developing the resin-coated film after the exposure.

In the step (1), the photosensitive resin composition is applied onto a substrate to form a resin-coated film.

Examples of the substrate include a semiconductor substrate, a glass substrate, a silicon substrate, and a substrate formed by providing various kinds of metal films on a surface of a semiconductor plate, a glass plate, or silicon plate. The shape of the substrate is not particularly limited. The shape may be a flat-plate shape or a shape formed by providing a recessed part (hole) in a flat plate as in a silicon wafer. In a case of a substrate provided with a recessed part and further having a copper film on the surface, a copper film may be provided in the bottom of the recessed part as in a TSV structure.

As the method for applying a photosensitive resin composition, for example, a spray method, a roll coating method, a spin coating method, a slit-die coating method, a bar coating method, or an ink jet method can be adopted, and particularly, a spin coating method is preferable. In a case of a spin coating method, the rotation speed is usually 800 to 3000 rpm, and preferably 800 to 2000 rpm, and the rotation time is usually 1 to 300 seconds, and preferably 5 to 200 seconds. After the spin coating of the photosensitive resin composition, the obtained resin-coated film is dried by heating at usually 50 to 180° C., preferably 60 to 150° C., and furthermore preferably 70 to 110° C. for around 1 to 30 minutes.

The film thickness of the resin-coated film is usually 0.1 to 200 μm, preferably 5 to 150 μm, more preferably 20 to 100 μm, and furthermore preferably 30 to 80 μm.

In the step (2), the resin-coated film is exposed. That is, in the step (3), the exposure is performed selectively on the resin-coated film so that a resist pattern is obtained.

The exposure is performed on the above coated film usually through a desired photomask by using, for example, a contact aligner, a stepper, or a scanner. As the exposure light, light having a wavelength of 200 to 500 nm (for example: i-line (365 nm)) is used. The amount of exposure differs depending on the type and mixing amount of the component in the resin-coated film, the thickness of the coated film, and the like, and is usually 1 to 10,000 mJ/cm² in a case where an i-line is used as the exposure light.

Further, heat treatment can also be performed after the exposure. The conditions of the heat treatment after the exposure are appropriately determined depending on the type and mixing amount of the component in the resin-coated film, the thickness of the coated film, and the like, and are usually at 70 to 180° C. for 1 to 60 minutes.

In the step (3), the exposed resin-coated film is developed. In this way, a resist pattern is formed.

As the developer, an aqueous solution of, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene, or 1,5-diazabicyclo[4.3.0]-5-nonane can be used. Further, an aqueous solution prepared by adding a water-soluble organic solvent such as methanol or ethanol and a surfactant each in an appropriate amount to the above aqueous solution of alkalis can also be used as the developer.

The development time varies depending on the type and mixing ratio of each component in the composition, the thickness of the coated film, and the like, and is usually 30 to 600 seconds. As the method for development, any one of a liquid filling method, a dipping method, a paddle method, a spray method, a shower development method, and the like may be used.

The resist pattern may be washed with running water or the like. After the washing, the resist pattern may be air dried by using an air gun or the like, or may be dried under heating on a hot plate, in an oven, or the like.

Since the photosensitive resin composition of the present invention contains a specific compound to be described later in a specific proportion as the polymerizable compound (B), a thick-film resist pattern having excellent resolution can be formed by the above method for forming a resist pattern.

[Method for Producing Plated Formed Product]

The method for producing a plated formed product of the present invention is characterized by including a step of performing plating treatment on the substrate by using the resist pattern formed by the above-described method for forming a resist pattern as the mask.

Examples of the plated formed product include a bump, and wiring.

The formation of the resist pattern is performed in accordance with the above-described method for forming a resist pattern.

Examples of the plating treatment include a wet plating treatment such as electroplating treatment, electroless plating treatment, or hot-dip plating treatment, and a dry plating treatment such as chemical vapor deposition, or sputtering.

In a case where wiring and connection terminals are formed in the processing at a wafer level, the plating treatment is usually performed by electroplating treatment.

Before performing the electroplating treatment, a pretreatment such as ashing treatment, flux treatment, and desmear treatment can be performed on an inner wall surface of a resist pattern in order to enhance the affinity between the inner wall surface of a resist pattern and the plating liquid.

In a case of the electroplating treatment, a layer formed on the inner wall of the resist pattern by sputtering or electroless plating treatment can be used as a seed layer, and in a case where a substrate with a metal film on the surface is used as the substrate, the metal film can also be used as a seed layer.

A barrier layer may be formed before the seed layer is formed, and the seed layer can be used as the barrier layer. Examples of the plating liquid used for electroplating treatment include a copper plating liquid containing copper sulfate, copper pyrophosphate, or the like; a gold plating liquid treatment containing gold potassium cyanide; and a nickel plating liquid containing nickel sulfate or nickel carbonate.

As the plating treatment, different plating treatments can be sequentially performed. For example, a copper-pillar bump can be formed by performing first copper plating treatment, next nickel plating treatment, and then melting solder plating treatment.

After the step of performing the plating treatment, a step of removing the resist pattern with a resist peeling liquid may be performed. The resist pattern can be removed in accordance with a conventional method. In a case where the compound (B1) represented by the above formula (1) and having an isocyanuric ring is contained, the photosensitive resin composition of the present invention can peel the resist pattern by utilizing the decomposition of a base of the isocyanuric ring, and the peelability of the resist pattern is favorable.

### EXAMPLES

Hereinafter, the present invention will be described more specifically by way of Examples, however, the present invention is not limited to these Examples. In the description of the following Examples and the like, the term “parts” is used in the meaning of “parts by mass”.

The weight average molecular weight (Mw) of the alkali-soluble resin is a value calculated in terms of polystyrene by gel permeation chromatography method under the following conditions.
Column: Connection of columns TSK-M and TSK2500 manufactured by Tosoh Corporation in series
Solvent: Tetrahydrofuran
Column temperature: 40° C.
Detection method: Refractive index method
Standard substance: Polystyrene
GPC apparatus: Device name “HLC-8220-GPC” manufactured by Tosoh Corporation

<Production of Photosensitive Resin Composition>

### Examples 1A to 13A, and Comparative Examples 1A to 5A

With the use of propylene glycol monomethyl ether acetate as the solvent, each of the components in the amounts shown in the following Table 1 was added to the solvent so as to have a solid content concentration of 65% by mass as shown in Table 1, and mixed, and each of the obtained mixtures was filtered through a capsule filter (pore diameter of 3 μm) to produce photosensitive resin compositions of Examples 1A to 13A and Comparative Examples 1A to 5A.

TABLE 1

| | | Example | Example | Example | Example | Example | Example | Example | Example | Example | Example |
|---|---|---|---|---|---|---|---|---|---|---|---|
| Component (parts by mass) | | 1A | 2A | 3A | 4A | 5A | 6A | 7A | 8A | 9A | 10A |
| Alkali-soluble | (A11) | 100 | 100 | 100 | 100 | 100 | 100 | 100 | 100 | 100 | |
| resin (A) | (A12) | | | | | | | | | | 100 |
| | (A13) | | | | | | | | | | |
| Polymerizable | (B11) | 42 | 52 | 42 | 42 | | 42 | 42 | 42 | | 52 |
| compound (B1) | (B12) | | | | | 74 | | | | 52 | |
| | (B13) | | | | | | | | | | |
| Polymerizable | (B21) | | | 8 | | | | | | | |
| compound (B2) | (B22) | | | | | | | | | | |
| | (B23) | | | | 8 | | | | | | |
| | (B24) | 4.5 | | | | | 3.3 | 8 | | | |
| | (B25) | 3 | | | | | 4 | | | | |
| | (B26) | | | | | | | | 12 | | |
| Photoradical | (C1) | 4 | 4 | 4 | 4 | 4 | 4 | 4 | 4 | 4 | 4 |
| polymerization | (C2) | 0.5 | 0.5 | 0.5 | 0.5 | 0.5 | 0.5 | 0.5 | 0.5 | 0.5 | 0.5 |
| initiator (C) | (C3) | | | | | | | | | | |
| Others (E) | (E1) | 0.1 | 0.1 | 0.1 | 0.1 | 0.1 | 0.1 | 0.1 | 0.1 | 0.1 | 0.1 |

| | | | | | | | | | | |
|---|---|---|---|---|---|---|---|---|---|---|
| Solid content concentration | 65 | 65 | 65 | 65 | 65 | 65 | 65 | 65 | 65 | 65 |
| (% by mass) | | | | | | | | | | |
| Content ratio of the | 18 | 22 | 18 | 18 | 27 | 18 | 18 | 17 | 22 | 22 |
| polymerizable compound | | | | | | | | | | |
| (B1) contained in | | | | | | | | | | |
| composition | | | | | | | | | | |
| (% by mass) | | | | | | | | | | |
| Content ratio of the | 28 | 34 | 28 | 28 | 43 | 28 | 28 | 30 | 34 | 34 |
| polymerizable compound | | | | | | | | | | |
| (B1) to the total content of | | | | | | | | | | |
| the alkali-soluble resin (A) | | | | | | | | | | |
| and the polymerizable | | | | | | | | | | |
| compound (B) | | | | | | | | | | |
| (% by mass) | | | | | | | | | | |
| Content ratio of the | 85 | 100 | 84 | 84 | 100 | 85.2 | 84 | 78 | 93 | 100 |
| compound (B1) contained in | | | | | | | | | | |
| polymerizable compound | | | | | | | | | | |
| (B) | | | | | | | | | | |
| (% by mass) | | | | | | | | | | |

| | | Example | Example | Example | Comparative | Comparative | Comparative | Comparative | Comparative |
|---|---|---|---|---|---|---|---|---|---|
| Component (parts by mass) | | 11A | 12A | 13A | Example 1A | Example 2A | Example 3A | Example 4A | Example 5A |
| Alkali-soluble | (A11) | 100 | 100 | | 100 | 100 | 100 | 100 | 100 |
| resin (A) | (A12) | | | | | | | | |
| | (A13) | | | 100 | | | | | |
| Polymerizable | (B11) | 52 | | 52 | | 29 | | | |
| compound (B1) | (B12) | | | | | | 20 | | |
| | (B13) | | 52 | | | | | | |
| Polymerizable | (B21) | | | | | | | 52 | |
| compound (B2) | (B22) | | | | 42 | | | | |
| | (B23) | | | | 8 | | 5 | | 52 |
| | (B24) | | | | | | | | |
| | (B25) | | | | | | | | |
| | (B26) | | | | | | | | |
| Photoradical | (C1) | 6 | 4 | 4 | 4 | 4 | 4 | 4 | 4 |
| polymerization | (C2) | | 0.5 | 0.5 | 0.5 | 0.5 | 0.5 | 0.5 | 0.5 |
| initiator (C) | (C3) | 0.4 | | | | | | | |
| Others (E) | (E1) | 0.1 | 0.1 | 0.1 | 0.1 | 0.1 | 0.1 | 0.1 | 0.1 |

| | | | | | | | | |
|---|---|---|---|---|---|---|---|---|
| Solid content concentration | 65 | 65 | 65 | 65 | 65 | 65 | 65 | 65 |
| (% by mass) | | | | | | | | |
| Content ratio of the | 21 | 22 | 22 | 0 | 14 | 10 | 0 | 0 |
| polymerizable compound | | | | | | | | |
| (B1) contained in | | | | | | | | |
| composition | | | | | | | | |
| (% by mass) | | | | | | | | |
| Content ratio of the | 34 | 34 | 34 | 0 | 22 | 16 | 34 | 34 |
| polymerizable compound | | | | | | | | |
| (B1) to the total content of | | | | | | | | |
| the alkali-soluble resin (A) | | | | | | | | |
| and the polymerizable | | | | | | | | |
| compound (B) | | | | | | | | |
| (% by mass) | | | | | | | | |
| Content ratio of the | 100 | 100 | 100 | 0 | 100 | 80 | 0 | 0 |
| compound (B1) contained in | | | | | | | | |
| polymerizable compound | | | | | | | | |
| (B) | | | | | | | | |
| (% by mass) | | | | | | | | |

Details of respective components shown in Table 1 are as follows.

Alkali-soluble resin (A11): Acrylic resin having structural units with symbols a to c, represented by the following formula (A11) (Mw: 13,000, and content ratio of structural units a to c: a/b/c=10/15/75 (k by mass))

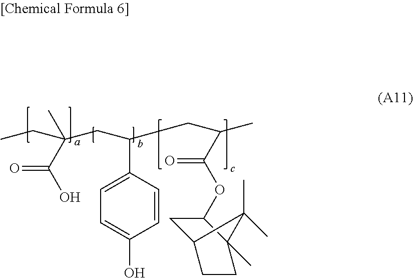

Alkali-soluble resin (A12): Acrylic resin having structural units with symbols a to c, represented by the following formula (A12) (Mw: 12,000, and content ratio of structural units a to c: a/b/c=50/30/20 (% by mass))

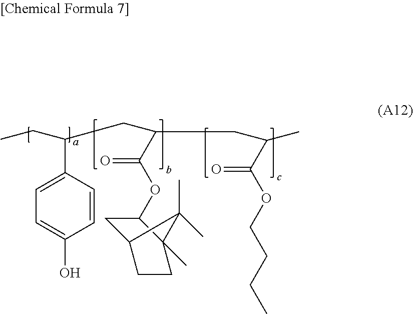

Alkali-soluble resin (A13): Acrylic resin having structural units with symbols a to c, represented by the following formula (A13) (Mw: 12,000, and content ratio of structural units a to c: a/b/c=10/15/75 (T by mass))

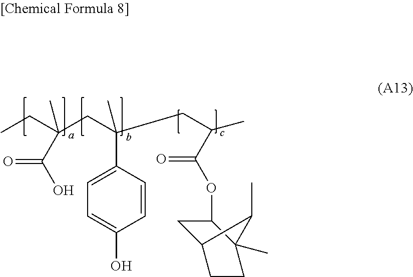

Polymerizable compound (B11): Compound represented by the following formula (B11)

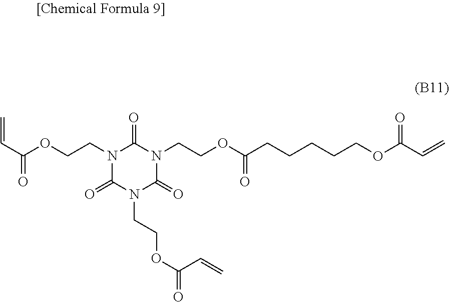 [SMILES: C=CC(=O)OCCCCCC(=O)OCCn1c(=O)n(CCOC(=O)C=C)c(=O)n(CCOC(=O)C=C)c1=O]

Polymerizable compound (B12): Compound represented by the following formula (B12)

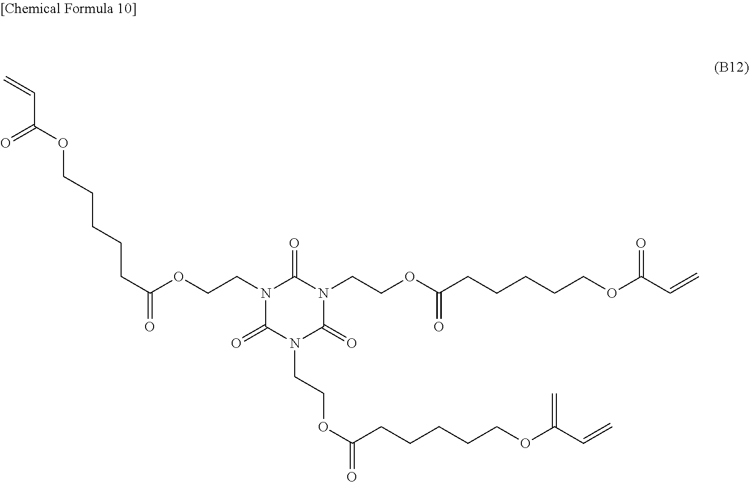 [SMILES: C=CC(=C)OCCCCCC(=O)OCCn1c(=O)n(CCOC(=O)CCCCCOC(=O)C=C)c(=O)n(CCOC(=O)CCCCCOC(=O)C=C)c1=O]

Polymerizable Compound (B13):

With reference to Example 2 in JP 2015-057375 A, the polymerizable compound (B13) represented by the following formula (B13) was synthesized in a similar manner as in Example 2 except that the methacryloyl chloride was changed to a compound represented by the following formula (b1).

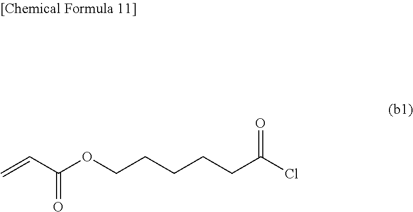

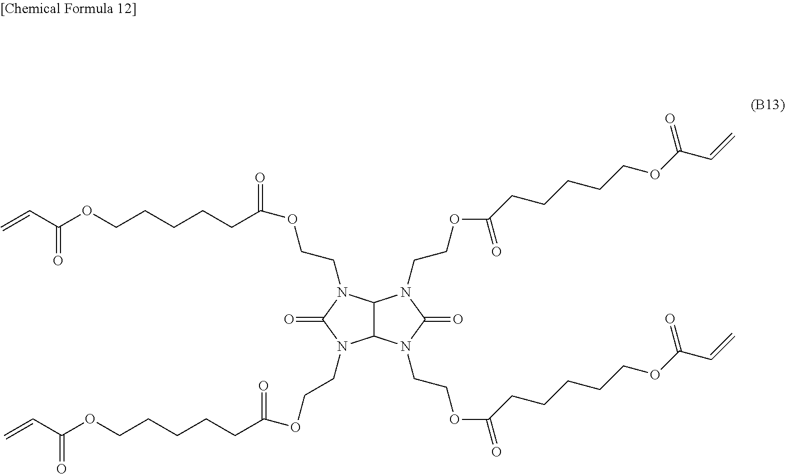 [SMILES: C=CC(=O)OCCCCCC(=O)OCCN1C(=O)N(CCOC(=O)CCCCCOC(=O)C=C)C2C1N(CCOC(=O)CCCCCOC(=O)C=C)C(=O)N2CCOC(=O)CCCCCOC(=O)C=C]

Polymerizable compound (B21): Compound represented by the following formula (B21)

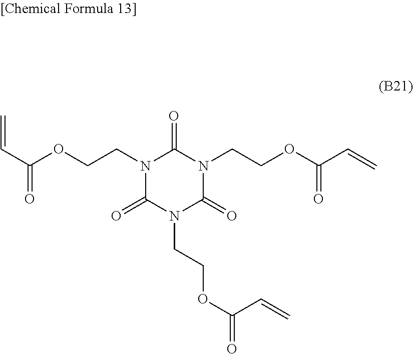 [SMILES: C=CC(=O)OCCn1c(=O)n(CCOC(=O)C=C)c(=O)n(CCOC(=O)C=C)c1=O]

Polymerizable compound (B22): Polyester acrylate (trade name: “ARONIX M-8060”, manufactured by TOAGOSEI CO., LTD.)

Polymerizable compound (B23): Compound represented by the following formula (B23)

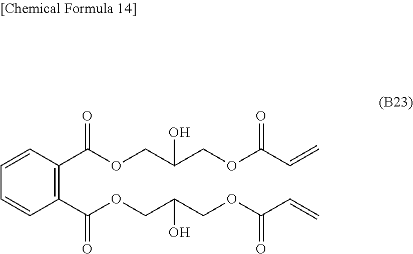 [SMILES: C=CC(=O)OCC(O)COC(=O)c1ccccc1C(=O)OCC(O)COC(=O)C=C]

Polymerizable compound (B24): Compound represented by the following formula (B24)

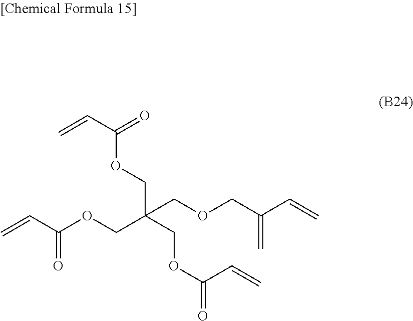 [SMILES: C=CC(=C)COCC(COC(=O)C=C)(COC(=O)C=C)COC(=O)C=C]

Polymerizable compound (B25): Compound represented by the following formula (B25)

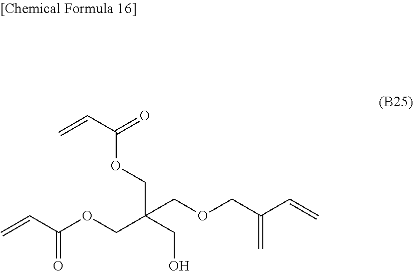 [SMILES: C=CC(=C)COCC(CO)(COC(=O)C=C)COC(=O)C=C]

Polymerizable compound (B26): Compound represented by the following formula (B26)

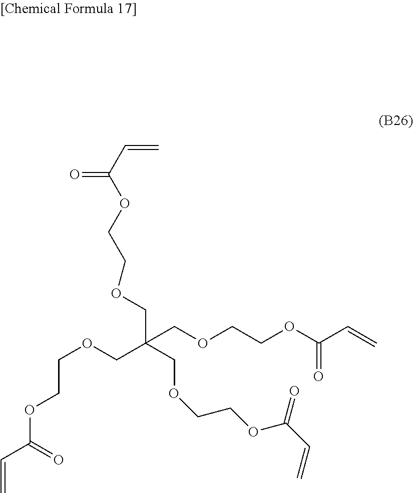 [SMILES: C=CC(=O)OCCOCC(COCCOC(=O)C=C)(COCCOC(=O)C=C)COCCOC(=O)C=C]

Photoradical polymerization initiator (C11): 2, 4, 6-Trimethylbenzoyldiphenylphosphine oxide

Photoradical polymerization initiator (C12): Compound represented by the following formula (C12)

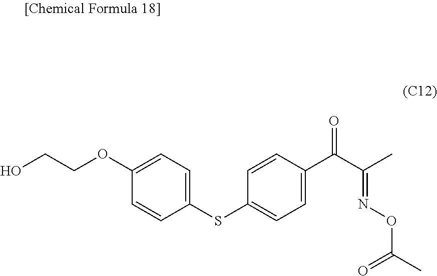 [SMILES: CC(=O)O/N=C(\C)C(=O)c1ccc(Sc2ccc(OCCO)cc2)cc1]

Photoradical polymerization initiator (C13): 1-[9-Ethyl-6-(2-methylbenzoyl)-9H-carbazol-3-yl]ethanone 1-(0-acetyloxime) (trade name: “IRGACURE OXE02”, manufactured by BASF)

Other component (E1): Diglycerin ethylene oxide adduct (average addition mole number: 18) of perfluorononenyl ether (product name: “Ftergent FTX-218”, manufactured by NEOS COMPANY LIMITED)

<Formation of Resist Pattern>

### Example 1B

The photosensitive resin composition of Example 1A was applied onto a substrate provided with a copper sputtered film on the 6-inch silicon wafer, by a spin coating method, and heated on a hot plate at 120° C. for 300 seconds to form a resin-coated film having a film thickness of 60 μm.

The coated film was exposed through a pattern mask by using a stepper (model “NSR-i12D”, manufactured by Nikon Corporation), and the exposed coated film was immersed in a 2.38% by mass aqueous solution of tetramethylammonium hydroxide for 200 seconds and developed to attempt to form resist patterns (hole patterns) of 10 μm in length×10 μm in width×60 μm in depth, 15 μm in length×15 μm in width×60 μm in depth, and 20 μm in length×20 μm in width×60 μm in depth.

The amount of exposure required for optimally forming a hole pattern of 20 μm in length×20 μm in width×60 μm in depth was determined. The “sensitivity” of the photosensitive resin composition was evaluated based on the following criteria. The evaluation results are shown in Table 2.

A: The amount of exposure was less than 100 mJ/cm².

B: The amount of exposure was 100 mJ/cm² or more and less than 200 mJ/cm².

C: The amount of exposure was 200 mJ/cm² or more.

D: The resolution was impossible.

In this regard, in a case where the resin-coated film having a film thickness of 60 μm was not able to be formed and the sensitivity was not able to be evaluated, the case was evaluated as “E”.

In addition, among the hole patterns that were attempted to be formed, the smallest formed hole pattern was determined. The “resolution” of the photosensitive resin composition was evaluated based on the following criteria. The evaluation results are shown in Table 2.

A: The smallest hole pattern was 10 μm in length×10 μm in width×60 μm in depth.

B: The smallest hole pattern was 15 μm in length×15 μm in width×60 μm in depth.

C: The smallest hole pattern was 20 μm in length×20 μm in width×60 μm in depth.

D: The resolution was impossible.

In this regard, in a case where the resin-coated film having a film thickness of 60 μm was not able to be formed and the resolution was not able to be evaluated, the case was evaluated as “E”.

### Examples 2B to 13B and Comparative Examples 1B to 5B

Resist patterns of Examples 2B to 13B and Comparative Examples 1B to 5B were formed in the same manner as in Example 1B except that photosensitive resin compositions shown in the following Table 2 were each used in place of the photosensitive resin composition of Example 1A. The sensitivity and the resolution were evaluated. The evaluation results are shown in Table 2.

TABLE 2

| | Photosensitive | | |
|---|---|---|---|
| | resin | Sensitivity | Resolution |
| | composition | (mJ/cm²) | (um) |
| Example 1B | Example 1A | B | B |
| Example 2B | Example 2A | B | A |
| Example 3B | Example 3A | B | B |
| Example 4B | Example 4A | B | B |
| Example 5B | Example 5A | A | B |
| Example 6B | Example 6A | B | B |
| Example 7B | Example 7A | B | B |
| Example 8B | Example 8A | A | B |
| Example 9B | Example 9A | A | B |
| Example 10B | Example 10A | B | B |
| Example 11B | Example 11A | B | B |
| Example 12B | Example 12A | B | B |
| Example 13B | Example 13A | B | B |
| Comparative | Comparative | C | C |
| Example 1B | Example 1A | | |
| Comparative | Comparative | D | D |
| Example 2B | Example 2A | | |
| Comparative | Comparative | D | D |
| Example 3B | Example 3A | | |
| Comparative | Comparative | D | D |
| Example 4B | Example 4A | | |
| Comparative | Comparative | E | E |
| Example 5B | Example 5A | | |

<Production of Plated Formed Product>

### Example 1C

By using the resist pattern formed in Example 1B as a mask, copper plating treatment was performed to produce a plated formed product. As the pretreatment for the copper plating treatment, ashing treatment with oxygen plasma (output of 100 W, oxygen flow rate of 100 milliliters, and treatment time of 60 seconds) was performed, and then water washing was performed. A substrate after the pretreatment was immersed in 1 L of a copper plating liquid (product name “MICROFAB Cu300”, manufactured by Electroplating Engineers of Japan Ltd.), and was subjected to the electroplating treatment for 15 minutes by setting the plating bath temperature to 40° C. and the current density to 2 A/dm².

After the copper plating treatment, the resist pattern was removed by immersing the substrate in a resist peeling liquid (product name “ELPAC THB-S17”, manufactured by JSR Corporation) at 40° C., and a copper-plated formed product was produced.

The time required for removing the resist pattern with the resist peeling liquid was measured. The “peelability of resist” was evaluated based on the following criteria. The evaluation results are shown in Table 3.

A: The time required for peeling was less than 120 seconds.

B: The time required for peeling was 120 seconds or more and less than 180 seconds.

C: The time required for peeling was 180 seconds or more.

In this regard, in a case where the resist pattern was not able to be formed and the peelability was not able to be evaluated, the case was evaluated as “D”.

Further, the presence or absence of the footing of the copper-plated formed product, which was caused by the infiltration of the copper plating liquid into the interface between the resist pattern and the substrate, was observed with an electron microscope, and the “shape of the plated formed product” was evaluated based on the following criteria. The evaluation results are shown in Table 3.

A: There is no footing in the copper-plated formed product.

B: There is footing in the copper-plated formed product.

In this regard, in a case where the resist pattern was not able to be formed and the shape of the plated formed product was not able to be evaluated, the case was evaluated as “C”.

### Examples 2C to 13C, and Comparative Examples 1C to 5C

Resist patterns of Examples 2C to 13C and Comparative Examples 1C to 5C were formed in the same manner as in Example 1C except that resist patterns shown in the following Table 2 were each used in place of the resist pattern formed in Example 1B, the resist peelability and the shape of the plated formed product were evaluated. The evaluation results are shown in Table 2.

TABLE 3

| | Resist | Resist | Shape of plated |
|---|---|---|---|
| | pattern | peelability | formed product |
| Example 1C | Example 1B | A | A |
| Example 2C | Example 2B | A | A |
| Example 3C | Example 3B | A | A |
| Example 4C | Example 4B | A | A |
| Example 5C | Example 5B | A | A |
| Example 6C | Example 6B | A | A |
| Example 7C | Example 7B | A | A |
| Example 8C | Example 8B | A | A |
| Example 9C | Example 9B | A | A |
| Example 10C | Example 10B | A | A |
| Example 11C | Example 11B | A | A |
| Example 12C | Example 12B | C | A |
| Example 13C | Example 13B | A | A |
| Comparative | Comparative | B | A |
| Example 1C | Example 1B | | |
| Comparative | Comparative | C | D |
| Example 2C | Example 2B | | |
| Comparative | Comparative | C | D |
| Example 3C | Example 3B | | |
| Comparative | Comparative | C | D |
| Example 4C | Example 4B | | |
| Comparative | Comparative | C | D |
| Example 5C | Example 5B | | |

1: A photosensitive resin composition comprising:
an alkali-soluble resin (A);
a polymerizable compound (B);
a photoradical polymerization initiator (C); and
a solvent (D), wherein the polymerizable compound (B) comprises at least one kind (B1) selected from the group consisting of a compound represented by formula (1) and a compound represented by formula (3), and a content ratio of the compound (B1) contained in the photosensitive resin composition is from 15 to 50% by mass, 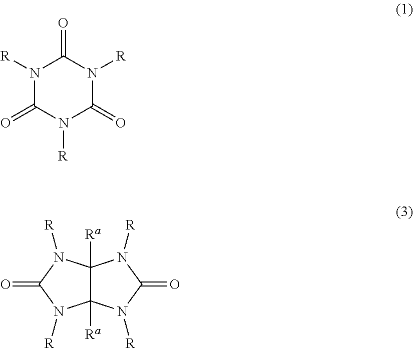
wherein in the formulas (1) and (3), Rs each independently represent any one of the groups represented by formulas (1-1) to (1-3), at least one R of the three Rs in the formula (1) and at least one R of the four Rs in the formula (3) each represent a group represented by formula (1-1), and R^{a}s in the formula (3) each independently represent a hydrogen atom, or a methyl group, 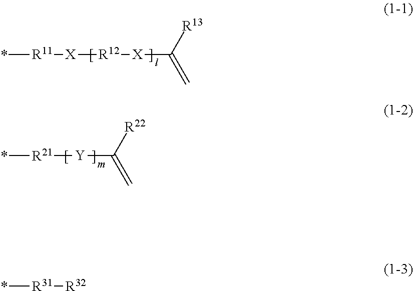
wherein in the formulas, R¹¹ represents an alkanediyl group having 1 to 10 carbon atoms, R¹² represents a hydrocarbon group having 3 to 10 carbon atoms, R¹³ represents a hydrogen atom, an alkyl group having 1 to 10 carbon atoms, or a fluorinated alkyl group having 1 to 10 carbon atoms, X represents —COO— or —OCO—; R²¹ represents an alkanediyl group having 1 to 3 carbon atoms, R²² represents a hydrogen atom, an alkyl group having 1 to 7 carbon atoms, or a fluorinated alkyl group having 1 to 7 carbon atoms, Y represents —COO— or —OCO—; R³¹ represents an alkanediyl group having 1 to 3 carbon atoms, R³² represents a hydroxyl group, a carboxyl group, a mercapto group, or an epoxy group; 1 is an integer of 1 to 3; and m is an integer of 0 to 1.

2: The photosensitive resin composition according to claim 1, wherein a content ratio of the compound (B1) to the total content of the alkali-soluble resin (A) and the polymerizable compound (B) is from 20 to 50% by mass.

3: The photosensitive resin composition according to claim 1, wherein a content ratio of the compound (B1) contained in the polymerizable compound (B) is from 50 to 100% by mass.

4: The photosensitive resin composition according to claim 1, wherein the polymerizable compound (B1) is a compound represented by the formula (1).

5: A method for forming a resist pattern comprising:
forming a resin-coated film by applying the photosensitive resin composition according to claim 1 onto a substrate;
exposing the resin-coated film; and
developing the exposed resin-coated film.

6: A method for producing a plated formed product comprising performing plating treatment by using the resist pattern formed by the method for forming a resist pattern according to claim 5 as a mask.
